(19) United States
(12) Patent Application Publication
(10) Pub. No.: US 2026/0362689 A1
(43) Pub. Date: Nov. 12, 2026

(54) MEMORY PILLAR SURROUNDED BY BARRIER LAYER THAT IS SELF-ALIGNED

(71) Applicant: Micron Technology, Inc., Boise, ID (US)

(72) Inventors: Kar Wui Thong, Boise, ID (US); Joel D. Peterson, Boise, ID (US); Sangeetha P. Komanduri, Boise, ID (US)

(21) Appl. No.: 19/669,624

(22) Filed: May 6, 2026

Related U.S. Application Data
(60) Provisional application No. 63/804,420, filed on May 12, 2025.

(51) Int. Cl. H10B 41/27; H10B 41/35

(52) U.S. Cl. CPC H10B 41/27; H10B 41/35

(57) ABSTRACT

An apparatus may include a stack of layers that includes an upper deck over a lower deck. A pillar associated with a string of memory cells may pass through the stack of layers and include a lower segment and a middle segment in the lower deck, along with an upper segment in the upper deck. The pillar may be surrounded by a dielectric layer and a barrier layer that is self-aligned and isolates the pillar from the stack of layers. In some examples, a portion of the barrier layer surrounding the lower segment may be thicker than a portion of the barrier layer surrounding the middle segment and the upper segment. Further, a thickness of the barrier layer or the dielectric layer may be substantially uniform within a transitional region between the upper deck and the lower deck.

### CROSS REFERENCE

The present Application for Patent claims the benefit of U.S. Provisional Patent Application No. 63/804,420 by Thong et al., entitled “MEMORY PILLAR SURROUNDED BY BARRIER LAYER THAT IS SELF-ALIGNED,” filed May 12, 2025, assigned to the assignee hereof, and expressly incorporated by reference herein.

### TECHNICAL FIELD

The following relates to one or more systems for memory, including an apparatus having a memory pillar surrounded by a barrier layer that is self-aligned.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system, including at least a portion of an apparatus that supports a memory pillar surrounded by a barrier layer that is self-aligned.

FIG. 2 shows an example of a memory architecture that supports an apparatus having a memory pillar surrounded by a barrier layer that is self-aligned with examples as disclosed herein.

FIG. 3 shows an example three dimensional (3D) NAND structure that supports an apparatus having a memory pillar surrounded by a barrier layer that is self-aligned with examples as disclosed herein.

FIG. 4 shows an example of a manufacturing system that supports an apparatus having a memory pillar surrounded by a barrier layer that is self-aligned in accordance with examples as disclosed herein.

FIGS. 5A - 5N show stages of an example manufacturing process that supports formation of an apparatus having a memory pillar surrounded by a barrier layer that is self-aligned in accordance with examples as disclosed herein.

FIGS. 6A and 6B show a flowchart illustrating a method or methods that support an apparatus having a memory pillar surrounded by a barrier layer that is self-aligned in accordance with examples as disclosed herein.

### DETAILED DESCRIPTION

Some apparatuses (e.g., memory systems) include vertical planar memory cells or in-pillar memory cells, where the memory cells extend through a stack of layers formed over a semiconductive substrate (e.g., a 3D not-and (NAND) memory configuration). The stack may be a multi-deck structure including an upper deck (e.g., an upper level) of alternating dielectric layers and conductive layers over a lower deck (e.g., a lower level) of alternating and dielectric and conductive layers. A pillar that includes memory cells may include a lower segment and a middle segment (e.g., a facet) in the lower deck. The pillar may further include an upper segment in the upper deck. Further, a dielectric layer surrounding the pillar (e.g., a charge trapping layer) may be electrically isolated from the upper deck and the lower deck using a barrier layer.

In some cases, techniques to fabricate the pillar may include forming the lower deck, forming a cavity for the lower segment and the middle segment of the pillar in the lower deck, and forming a lower portion of the barrier layer along contours of the cavity. After formation of the upper deck over the lower deck, the techniques may further include forming an upper cavity in the upper deck for the upper segment of the pillar. However, tilt or overlay errors during formation of the cavity may cause a misalignment that reduces available process margins (e.g., critical dimensions) for joining an upper portion of the barrier layer with the lower portion of the barrier layer. The reduced available process margins may cause variation in a thickness of the barrier layer (e.g., “shaving”) across a transitional region between the upper deck and the lower deck, which may subsequently cause a variation or reduced thickness of the barrier layer or the dielectric layer in the transitional region to reduce a performance of the pillar (e.g., increase a degradation in a threshold voltage used to access memory cells in the pillar).

In examples described herein, an apparatus may include a semiconductive substrate and a stack of layers including alternating conductive and dielectric layers above the substrate. The stack of layers may include an upper deck over the lower deck. A pillar associated with a string of memory cells may pass through the stack of layers to the substrate. The pillar may include a lower segment and a middle segment (e.g., a facet) in the lower deck. The pillar may further include an upper segment in the upper deck. The pillar may be surrounded by a multi-layer structure including a dielectric layer (e.g., a charge trapping layer) and a barrier layer that is self-aligned. In some examples, a thickness of a portion of the barrier layer surrounding the lower segment may be greater than a thickness of a portion of the barrier layer surrounding the middle segment and the upper segment. Further, a thickness of the barrier layer or the dielectric layer may be substantially uniform in a transitional region between the upper deck and the lower deck.

In some examples, techniques that form the barrier layer may include self-aligning a portion of the barrier layer surrounding the upper segment and the middle segment with a portion of the barrier layer surrounding the lower segment. In these ways, a variation in a thickness of the barrier layer or the dielectric layer in the transitional region is reduced to improve a performance of the pillar (e.g., reduce a variation or degradation in voltages used by active word lines to access memory cells in the pillar).

In addition to applicability in memory systems as described herein, techniques associated with an apparatus having a memory pillar surrounded by a barrier layer that is self-aligned may be generally implemented to support cloud computing and storage applications. As the use of cloud computing to provide processing, storage, and networking services to multiple devices increases, many devices and systems may benefit from improved remote processing and storage capabilities. For example, increasing memory capacity or other capabilities may result in larger and more accessible storage options for users, and increasing memory access times may result in faster processing for computing or database applications. Implementing the techniques described herein may support cloud computing and storages techniques by increasing a reliability or a performance of cloud servers, resulting in an increased efficiency of cloud servers, among other benefits.

Features of the disclosure are illustrated and described in the context of systems, devices, and circuits. Features of the disclosure are further illustrated and described in the context of an example memory system, an example memory architecture, an example memory structure, an example manufacturing system, and example manufacturing process, and an example flowchart.

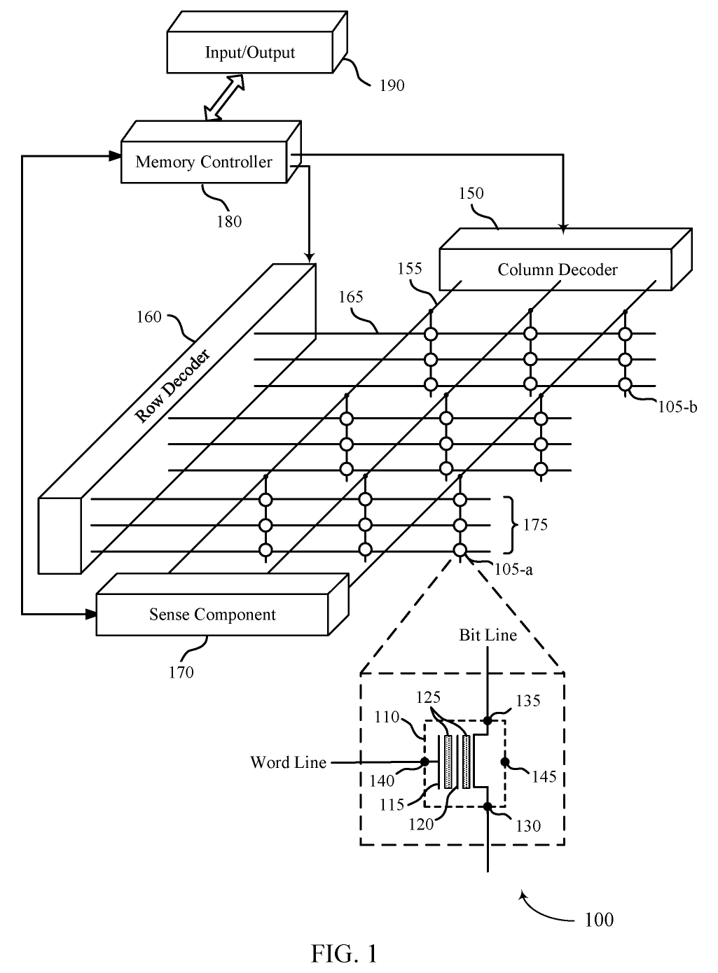

FIG. 1 shows an example of a memory system 100 that supports an apparatus having a memory pillar surrounded by a barrier layer that is self-aligned in accordance with examples as disclosed herein. FIG. 1 is an illustrative representation of various components and features of the memory system 100. As such, the components and features of the memory system 100 are shown to illustrate functional interrelationships, and not necessarily physical positions within the memory system 100. Further, although some elements included in FIG. 1 are labeled with a numeric indicator, some other corresponding elements are not labeled, even though they are the same or would be understood to be similar, in an effort to increase visibility and clarity of the depicted features.

The memory system 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such as a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

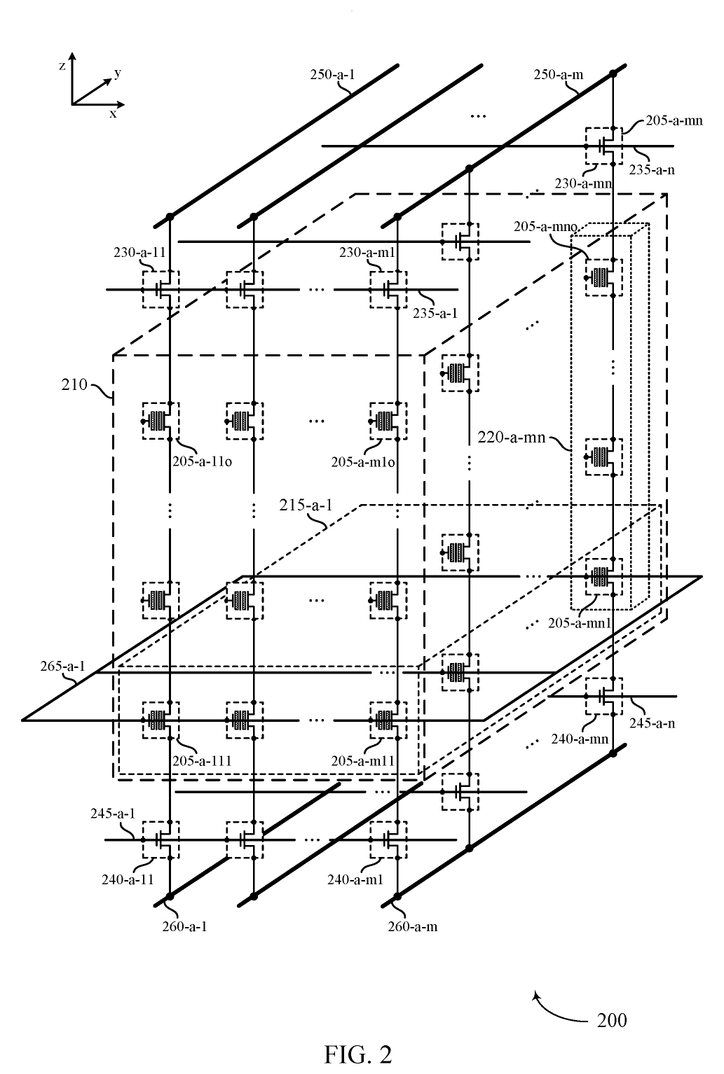

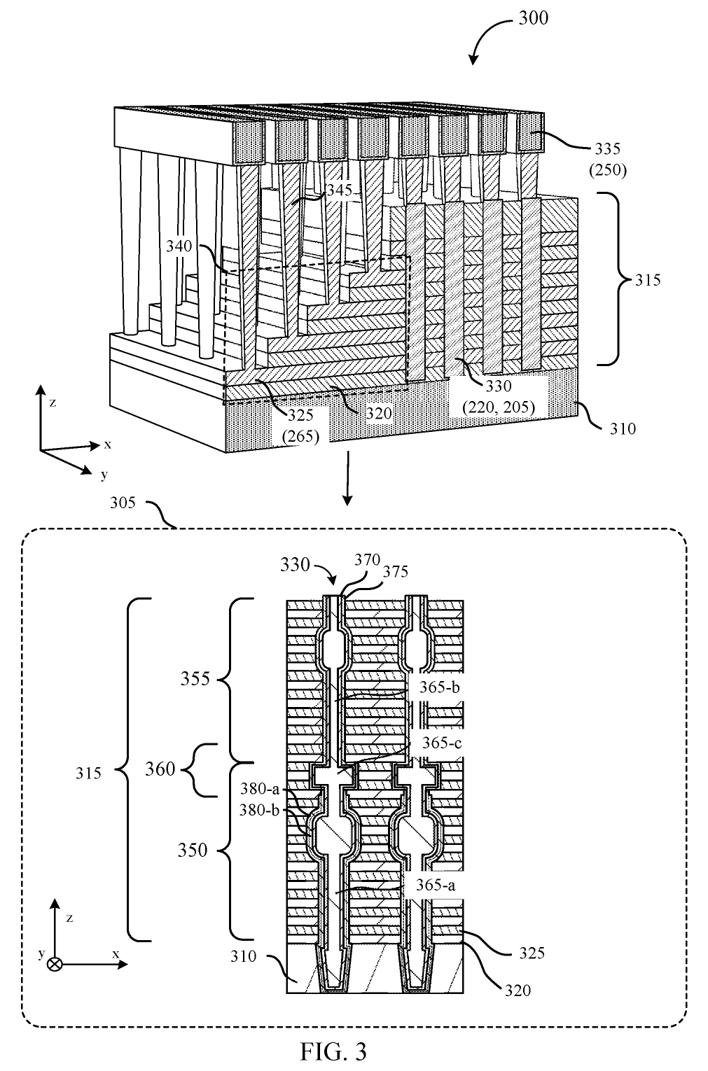

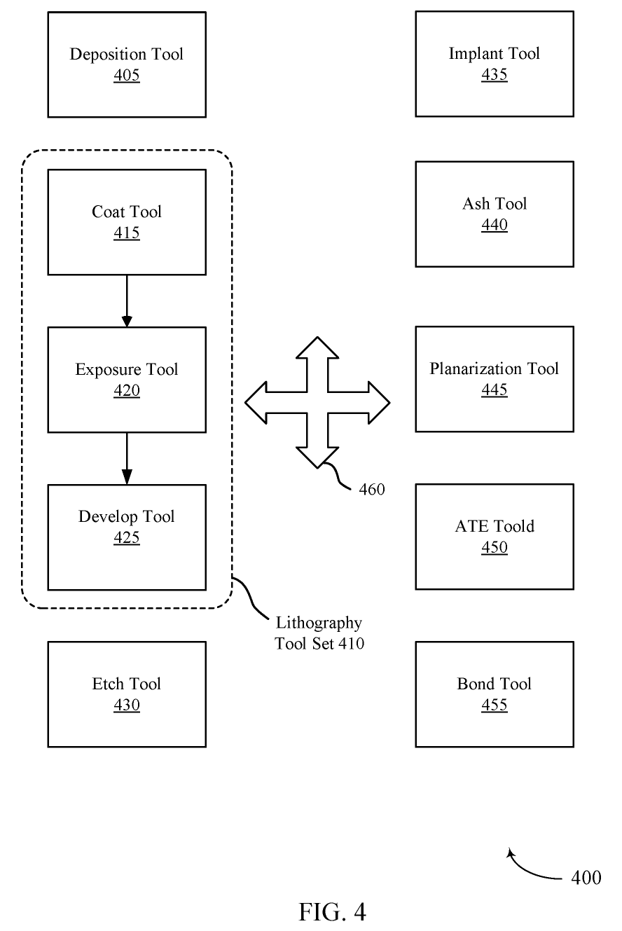

In some cases, a memory system 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory system 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory system 100.

As described in greater detail with reference to FIGS. 2 - 6, an architecture of the memory system 100 (e.g., an apparatus) may utilize a 3D NAND memory array including a semiconductive substrate and a stack of layers above the semiconductive substrate. The stack of layers may include an upper deck and a lower deck and a pillar passing through the stack of layers into the semiconductive substrate. The pillar, which may correspond to the memory cell stack 175, may include a lower segment and a middle segment (e.g., a facet) in the lower deck. The pillar may further include an upper segment in the upper deck. The pillar may be surrounded by a multi-layer structure including a dielectric layer (e.g., a charge trapping layer) and a barrier layer (e.g., a blocking oxide layer) that is self-aligned and isolates the pillar from conductive layers of the stack of layers. In some examples, a thickness of a portion of the barrier layer surrounding the lower segment may be greater than a thickness of a portion of the barrier layer surrounding the middle segment and the upper segment.

In some examples, techniques that form the barrier layer may include self-aligning a portion of barrier layer surrounding the upper segment of the pillar and the middle segment with a portion of the barrier layer surrounding the lower segment. In these ways, a variation in a thickness of the barrier layer or the dielectric layer in a transitional region is reduced to improve a performance of the pillar (e.g., reduce a variation or degradation in voltages used by active word lines to access memory cells in the pillar).

FIG. 2 shows an example of a memory architecture 200 that supports an apparatus having a memory pillar surrounded by a barrier layer that is self-aligned in accordance with examples as disclosed herein. The memory architecture 200 may be an example of a portion of a memory system, such as a memory system 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory system 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as a planar conductor (e.g., in an xy-plane) that is coupled with each of the memory cells 205 of the page 215.

In the example of memory architecture 200, the block 210 also may be divided into a set of strings 220 (e.g., a quantity of (m x n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity of the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between, electrically coupled between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 to be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget > VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget < VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

As described in greater detail with reference to FIGS. 3 - 6, a memory architecture 200 may utilize a 3D NAND memory array including a semiconductive substrate and a stack of layers above the semiconductive substrate. The stack of layers may include an upper deck and a lower deck and a pillar passing through the stack of layers into the semiconductive substrate. The pillar, which may correspond to a string 220, may include a lower segment and a middle segment (e.g., a facet) in the lower deck. The pillar may further include an upper segment in the upper deck. The pillar may be surrounded by a dielectric layer (e.g., charge trapping layer corresponding to a portion of the charge trapping structure 120) and a barrier layer (e.g., a blocking oxide layer) that isolates the pillar from the stack of layers. In some examples, a thickness of the barrier layer surrounding the lower segment may be greater than a thickness of the barrier layer surrounding the middle segment and the upper segment. Further, a thickness of the barrier layer or the dielectric layer may be substantially uniform throughout a transitional region between the upper deck and the lower deck.

FIG. 3 shows an example three dimensional (3D) NAND memory array 300 that supports an apparatus having a memory pillar surrounded by a barrier layer that is self-aligned with examples as disclosed herein. FIG. 3 includes an isometric view of the 3D NAND memory array 300 and a detailed section view 305 highlighting additional features that may be found in an implementation of the 3D NAND memory array 300. Such features may support an apparatus having a memory pillar surrounded by a barrier layer that is self-aligned in accordance with examples as disclosed herein.

As shown in FIG. 3, the 3D NAND memory array 300 may include a semiconductive substrate 310. The semiconductive substrate 310 (e.g., a substrate comprising silicon or another suitable semiconductive material) may support stack of layers 315. The stack of layers 315 may include one or more dielectric layers 320 (e.g., silicon dioxide or another suitable dielectric material) that alternative with one or more conductive layers 325 (e.g., tungsten or another suitable conductive material). Each conductive layer 325 may be associated with a word line of the 3D NAND memory array 300 (e.g., a word line 265 as described with reference to FIG. 2).

As further shown in FIG. 3, one or more pillar(s) 330 may pass through the stack of layers 315. Each pillar 330 (e.g., a memory pillar) may include a semiconductive layer (e.g., a layer of polysilicon or another suitable semiconductive material) that, in some examples, may be a semiconductive core. Each pillar may further include one or more dielectric layers (e.g., one or more layers of silicon nitride, silicon dioxide, or another suitable dielectric material) that are arranged in an annular fashion around the semiconductive layer. Each pillar 330 may be associated with a string of memory cells (e.g., a string 220 including a set of memory cells 205 as described with reference to FIG. 2) having a channel (e.g., the semiconductive layer) and a charge storage layer (e.g., a dielectric layer of the one or more dielectric layers).

As further shown in FIG. 3, the 3D NAND memory array 300 may include one or more conductive lines 335. Each conductive line 335 may include a conductive layer (e.g., a layer of tungsten or another suitable conductive material) surrounded by one or more dielectric layers (e.g., one or more layers of silicon nitride, silicon dioxide, or another suitable dielectric material). In some examples, one or more of the conductive lines 335 may be associated with a bit line (e.g., a bit line 250 as described with reference to FIG. 2).

As further shown in FIG. 3, the 3D NAND memory array 300 may include a staircase region 340. The staircase region 340 may include tiers that cascade and are formed from the stack of layers 315. The 3D NAND memory array 300 may further include one or more contact(s) 345 that extend into tiers the staircase region 340. In some examples, a contact 345 may include a conductive material (e.g., tungsten or another suitable conductive material). Alternatively, a contact 345 may include a semiconductive material (e.g., polysilicon or another suitable semiconductive material). In some examples, a contact 345 may electrically couple (e.g., electrically connect) with a conductive layer 325 in the staircase region. Additionally, or alternatively, and in some examples, a contact 345 may pass through a tier of the staircase region 340 and into the substrate 310. Additionally, or alternatively, and in some examples, a contact 345 may be electrically isolated from one or more conductive layers 325 within the staircase region 340.

In some examples, and as shown in detailed section view 305 of FIG. 3, the stack of layers 315 may be partitioned into decks or regions. For example, and as shown in the detailed section view 305, the stack of layers 315 may include a lower deck 350 and an upper deck 355. The stack of layers 315 may further include a transitional region 360 that spans layers of the lower deck 350 and the upper deck 355.

As shown in detailed section view 305, the pillar 330 may include a lower segment 365-a in the lower deck 350. Additionally, or alternatively, the pillar 330 may further include an upper segment 365-b in the upper deck 355. Additionally, or alternatively, the pillar 330 may further include a middle segment 365-c (e.g., a “middle segment”) in the lower deck 350, where the middle segment 365-c electrically couples (e.g., electrically connects) the upper segment 365-b with the lower segment 365-a. Said another way, and in some examples, the pillar 330 may be a multi-segment pillar.

In some examples, and as further shown in detailed section view 305, the transitional region 360 may include the middle segment 365-c. Additionally, or alternatively, the transitional region 360 may include at least a portion of the lower segment 365-a. Additionally, or alternatively, the transitional region 360 may include at least a portion of the upper segment 365-b. Additionally, or alternatively, the transitional region 360 may be proximate a dummy word line structure (e.g., an inactive word line structure).

As further shown in detailed section view 305, a multi-layer structure may surround the pillar 330. The multi-layer structure may include a dielectric layer 370 along the pillar 330 and a barrier layer 375 along the dielectric layer 370. In some examples, the dielectric layer 370 may include a silicon nitride material (or another suitable dielectric material) and be associated with a charge trapping layer of a memory cell. Further, and in some examples, the barrier layer 375 may include an oxide material (or another suitable dielectric material) and be a blocking layer (e.g., a blocking oxide (BO) layer) that prevents electron leakage from a memory cell to a conductive layer 325 (e.g., a word line). In some examples, a thickness of the dielectric layer 370 is greater than a thickness of the barrier layer 375.

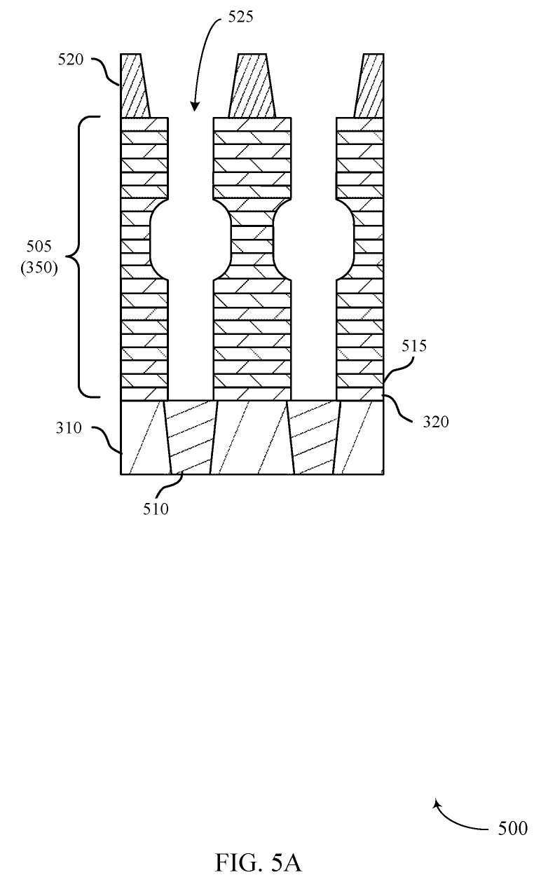

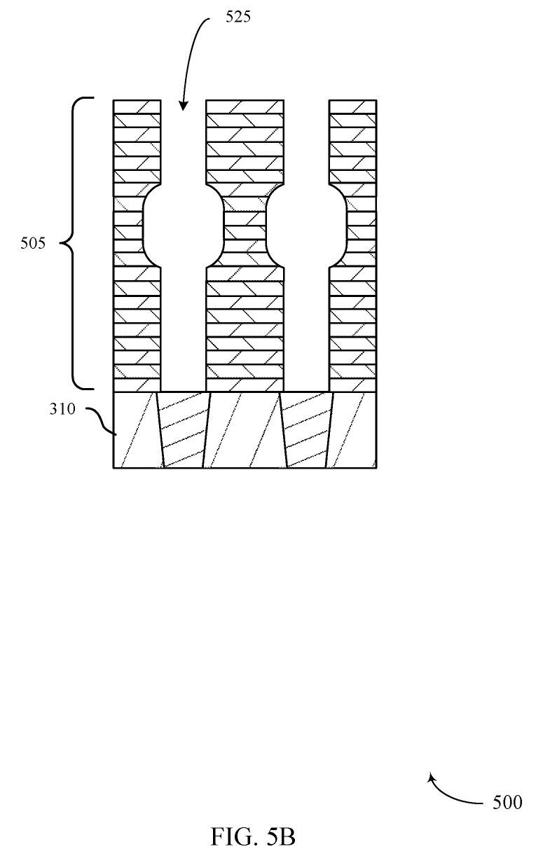

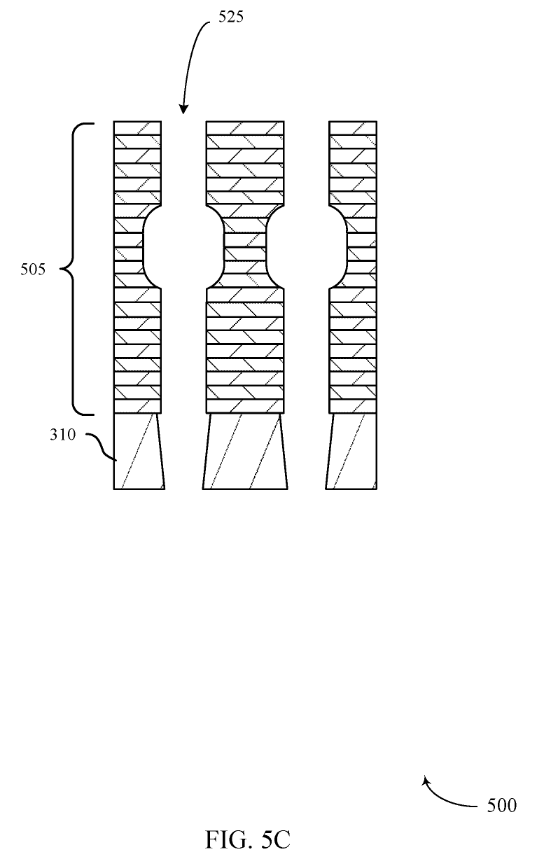

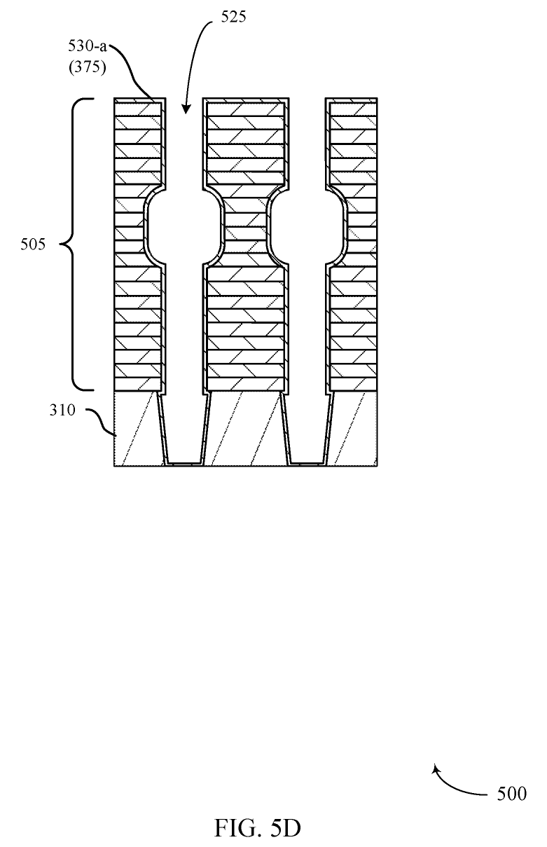

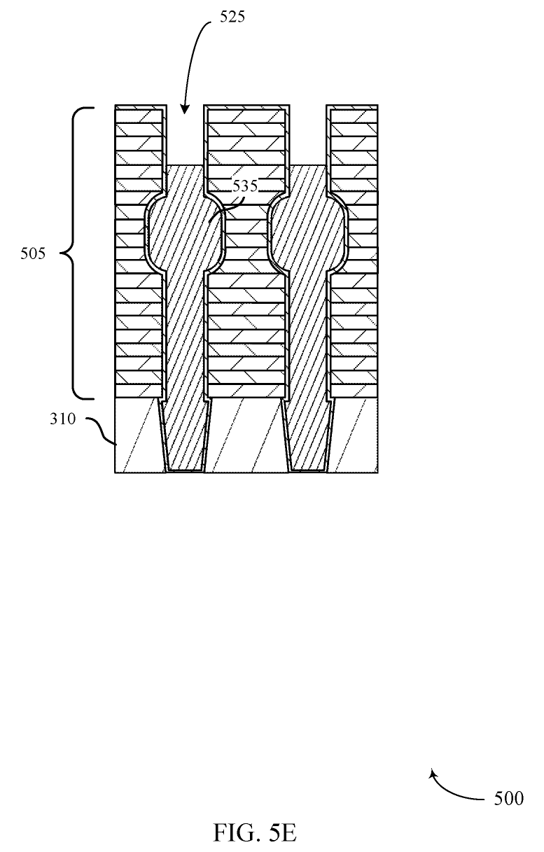

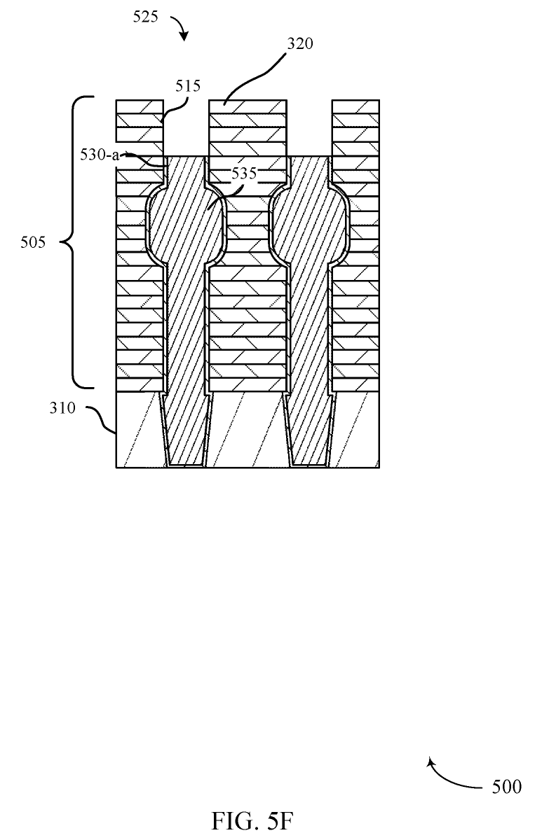

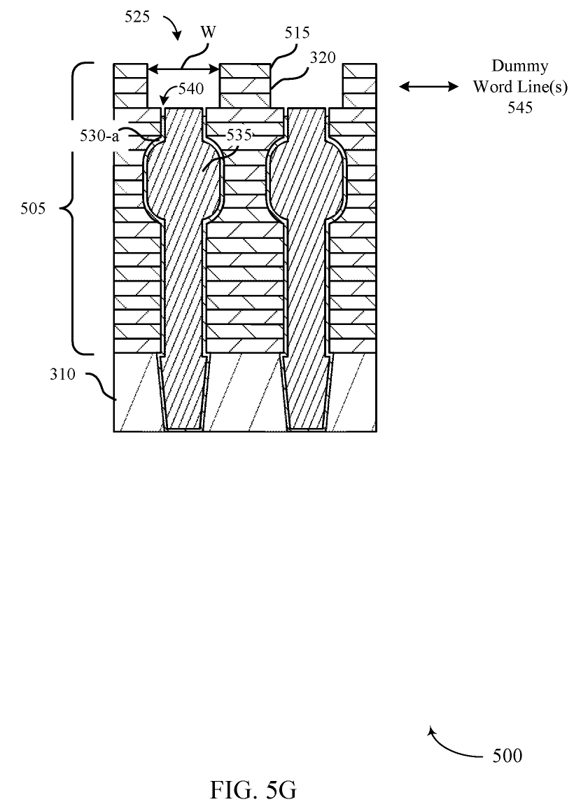

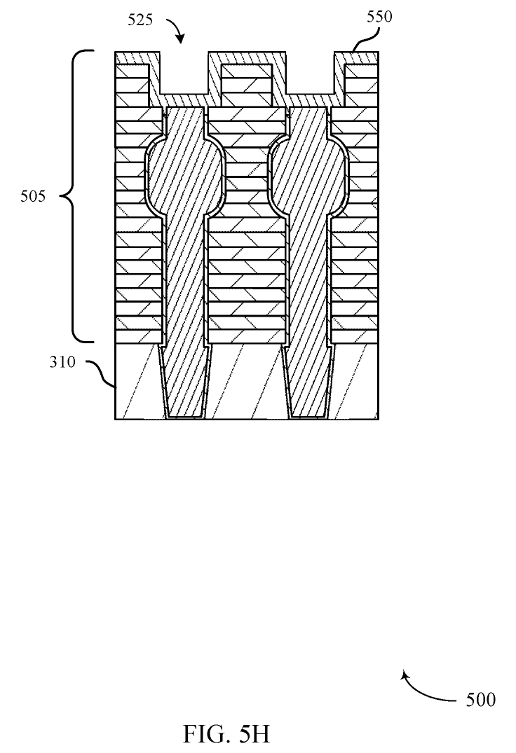

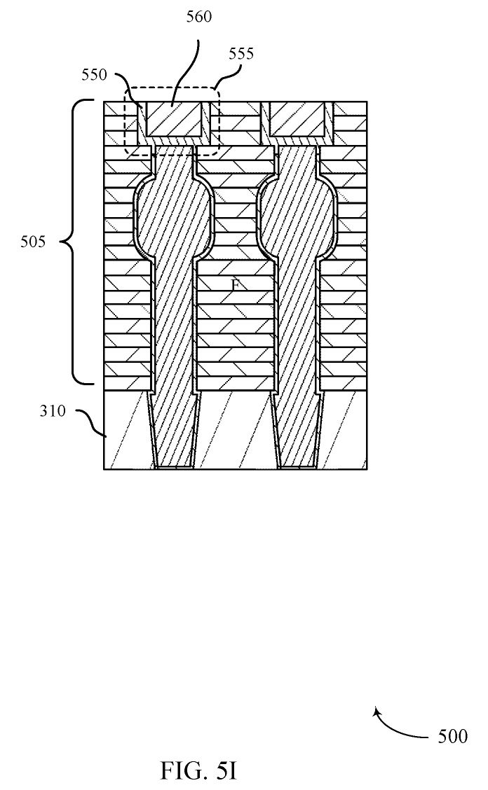

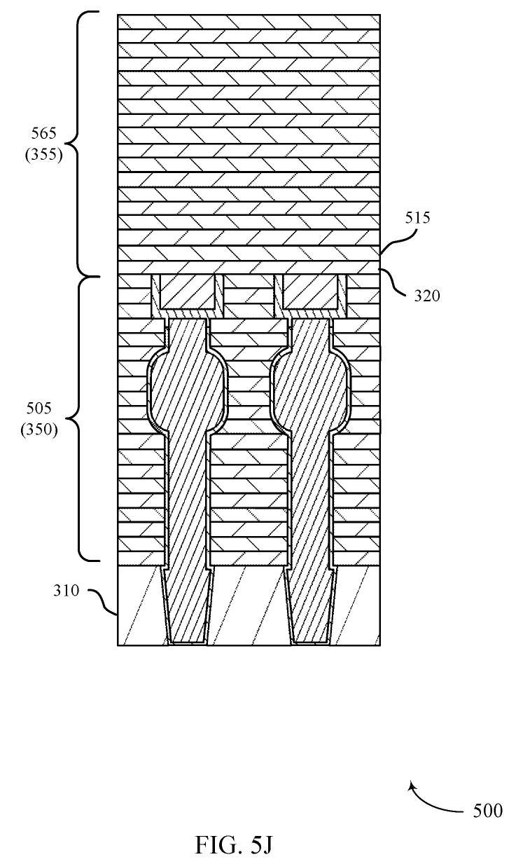

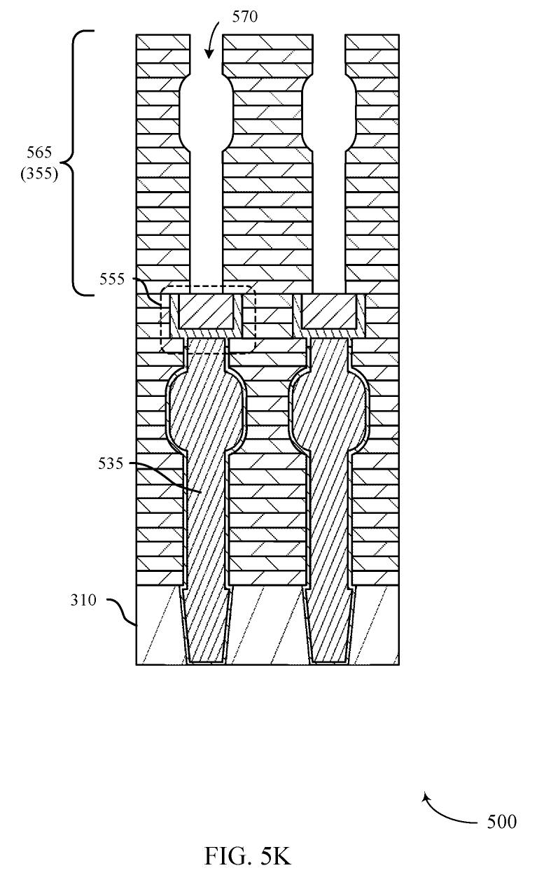

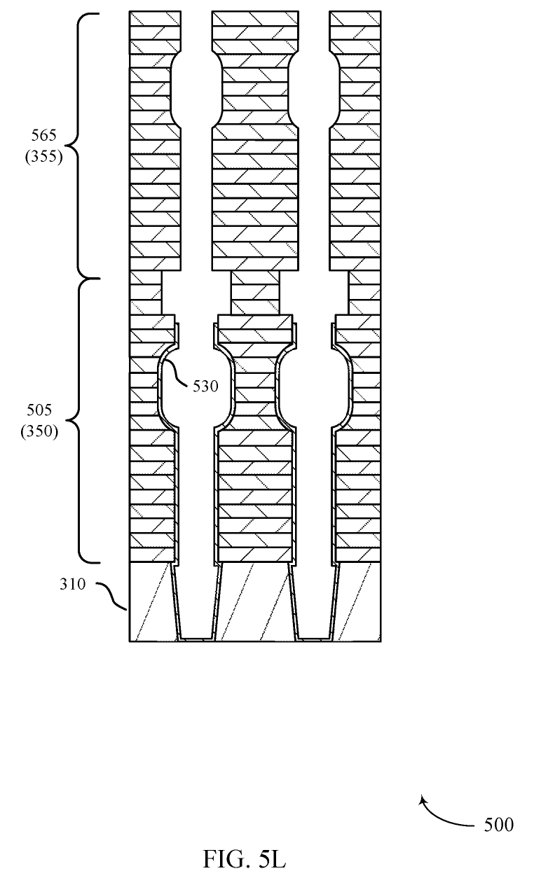

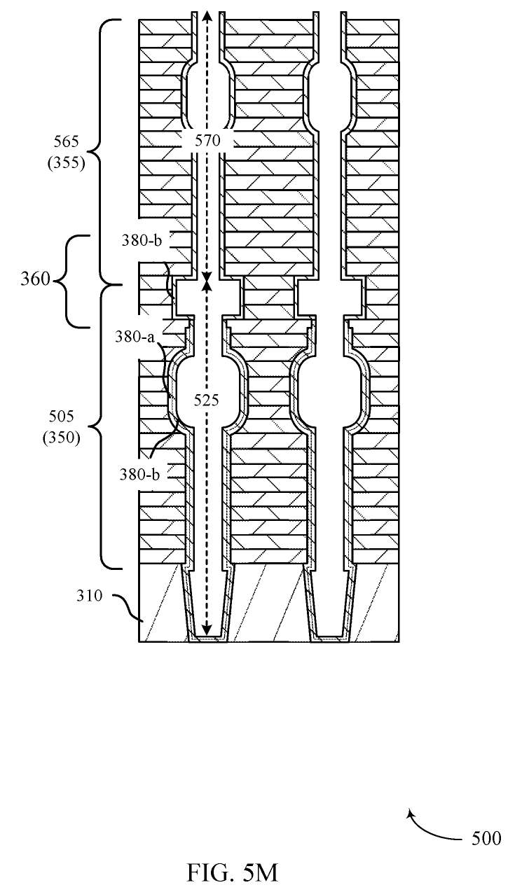

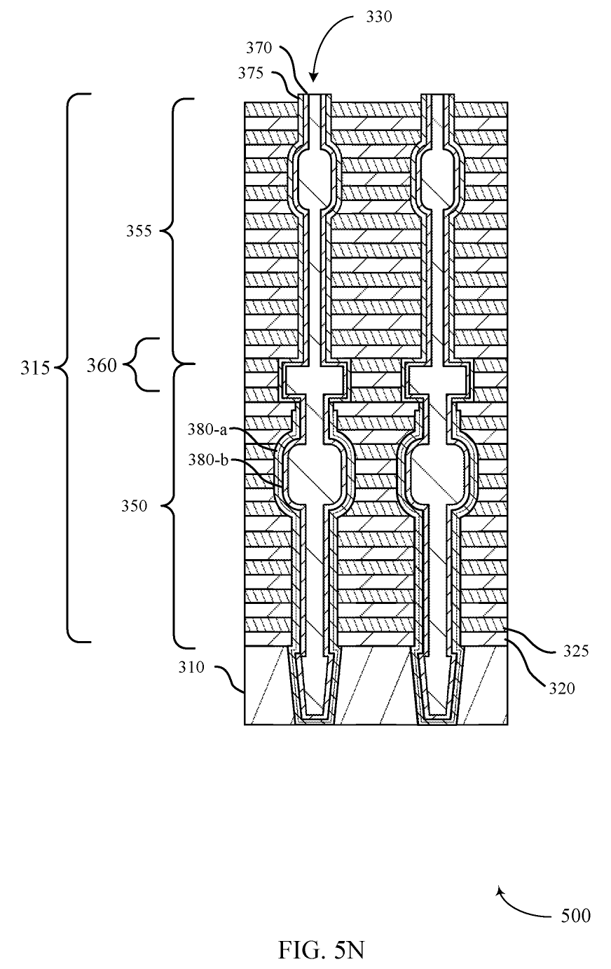

As described in greater detail in connection with FIGS. 5A - 5N, the barrier layer 375 may include one or more sublayers 380. For example, the barrier layer 375 may include a first portion comprising sublayer 380-a and 380-b (e.g., two sublayers) along the lower segment 365-a and a second portion comprising sub-layer 380-b (e.g., a single sublayer) along the upper segment 365-b and the middle segment 365-c. In some examples, the second portion may be at least partially along the first portion through self-alignment. . Additionally, or alternatively, the first portion comprising the two sublayers (e.g., a lower portion of the barrier layer 375) may have a thickness that is greater than that of the second portion comprising the single sublayer (e.g., an upper portion of the barrier layer 375).

Further, and as described in greater detail in connection with FIGS. 4 - 6, techniques to form the multi-layer structure may self-align the first and second portions of the barrier layer 375. Additionally, or alternatively, the techniques may cause a thickness of the dielectric layer 370 or the barrier layer 375 to be substantially uniform in the transitional region 360, thereby improving a performance of the pillar 330 (e.g., reduce a variation or degradation in voltages used by word lines to access memory cells associated with the pillar 330). Additionally, or alternatively, the techniques may cause the dielectric layer 370 or the barrier layer 375 to each have a substantially round, annular cross-sectional shape that is free of protrusions that may be extend towards the conductive layer(s) 325 proximate to the transitional region 360.

FIG. 4 shows an example manufacturing system 400 that supports an apparatus having a memory pillar surrounded by a barrier layer that is self-aligned. The manufacturing system 400, or portions thereof, may be located in a semiconductor foundry (e.g., a wafer foundry). In some examples, portions of the manufacturing system 400 may be part of front end of line (FEOL) operations used to fabricate active integrated circuitry (e.g., transistors, diodes, memory cells, or other active integrated circuitry) on a semiconductive substrate (e.g., a silicon wafer). Additionally, or alternatively, and in some examples, portions of the manufacturing system 400 may be part of back end of line (BEOL) operation used to fabricate interconnect structures (e.g., conductive traces, redistribution layers, vertical interconnect access structures (vias), or other interconnect structures) that electrically couple (e.g., electrically connect) the active integrated circuitry. Further, in some examples and as described in greater detail with reference to FIGS. 5A - 6, one or more tools of the manufacturing system 400 (e.g., semiconductor manufacturing tools) may be used to fabricate features that support a memory device having a memory pillar surrounded by a barrier layer that is self-aligned as described herein.

As shown in FIG. 4, the manufacturing system 400 may include a deposition tool 405. In some examples, the deposition tool 405 may be used as part of forming a layer of material (e.g., a layer of a semiconductive material, a layer of a conductive material, or a layer of a dielectric material). As part of forming the layer of the material, the deposition tool 405 may use a chemical vapor deposition (CVD) technique, a physical vapor deposition (PVD) technique, an oxidation technique, an epitaxial growth technique, or another suitable deposition technique, among other examples.

As further shown in FIG. 4, the manufacturing system 400 may include a lithography tool set 410. The lithography tool set 410 may include a coat tool 415, an exposure tool 420, and a develop tool 425. In some examples, the lithography tool set 410 may be used as part of forming a patterned layer of photoresist over and along a layer of material formed by the deposition tool 405. In some examples, the patterned layer of photoresist may be temporary and may be used as a template as part of forming features in the layer of material formed by the deposition tool 405.

In some examples, the coat tool 415 may be used to form a layer of photoresist (e.g., a layer of material that changes properties when irradiated) over and along a layer of material formed by the deposition tool 405. In some examples, and as part of forming the layer of photoresist, the coat tool 415 may use a spin coating technique that dispenses a controlled amount of liquid photoresist onto the layer of material and spin a semiconductive substrate carrying the layer of material to uniformly distribute the liquid photoresist and form the layer of photoresist. Additionally, or alternatively, and in some examples, the coat tool 415 may heat the layer of photoresist to cure the layer of photoresist.

In some examples, the exposure tool 420 may irradiate portions of a layer of photoresist. To irradiate the portions, the exposure tool 420 may generate electromagnetic waves (ultraviolet (UV) light waves, extreme ultraviolet (EUV) light waves, electron beams, or x-ray beams) and project the electromagnetic waves through a photomask (e.g., a reticle) to irradiate the portions. In some examples, the photomask may include a patterned layer of opaque material that replicates the portions, where the patterned layer is formed on a quartz or glass substrate that is transparent to the electromagnetic waves.

In some examples, the develop tool 425 may be used to develop a layer of photoresist as part of forming a patterned layer of photoresist (e.g., a template). As an example, and in a case where the layer of photoresist includes a “positive” photoresist material, portions of the layer of photoresist that are irradiated may be soluble to a developer solution and the develop tool 425 may dispense the developer solution to remove the irradiated portions. As another example, and in a case where the layer of photoresist includes a “negative” photoresist material, portions of the layer that are irradiated may be insoluble to a developer solution and the develop tool 425 may dispense the developer solution to remove portions of the layer of photoresist that are not irradiated.

As further shown in FIG. 4, the manufacturing system 400 may include an etch tool 430. In some examples, the etch tool 430 may be used to remove portions of one or more layers of material formed by the deposition tool 405. In some examples, removing the portions may include removing or exhuming the portions through a patterned layer of photoresist (e.g., a template) formed by the lithography tool set 410. To remove the portions, the etch tool 430 may use a wet etching technique, a dry etching technique, an ion beam etching technique, a laser etching technique, a chemical etching technique, a wet strip technique, or another suitable etching technique, among other examples.

As further shown in FIG. 4, the manufacturing system 400 may include an implant tool 435. In some examples, the implant tool 435 may be used to implant impurities (e.g., dopants) into a layer of material formed by the deposition tool. In some examples, implanting the impurities may modify electrical properties of the layer of material. Additionally, or alternatively, implanting the impurities may change a lattice structure to modify a mechanical property of the layer of material. To implant the impurities, the implant tool 435 may use an ion implanting technique, a plasma doping technique, a cluster/molecular implanting technique, a laser-assisted implanting technique, a beamline implanting technique, or another suitable implanting technique, among other examples.

As further shown in FIG. 4, the manufacturing system 400 may include an ash tool 440. In some examples, the ash tool 440 may be used to remove a patterned layer of photoresist. To remove the patterned layer of photoresist, the ash tool 440 may use a plasma-based oxidizing technique or another suitable ashing technique, among other examples.

As further shown in FIG. 4, the manufacturing system 400 may include a planarization tool 445. In some examples, the planarization tool 445 may be used to planarize a layer of material formed by the deposition tool 405. In some examples, planarizing the layer of material may remove a portion of the layer of material, reduce a thickness of the layer of material, polish the layer of material, or improve a uniformity of a thickness of the layer of material. To planarize the layer of material the planarization tool 445 may use a chemical/mechanical planarization (CMP) technique or another suitable planarization technique, among other examples.

As further shown in FIG. 4, the manufacturing system 400 may include an automated test equipment (ATE) tool 450. In some examples, the ATE tool 450 may be used to test (e.g., electrically test) or more features formed from layers of material on a semiconductive substrate. Testing may include testing one or more parametric parameters (a drive current, a resistivity, or a voltage) that may be indicative of a critical dimension (a line width, a thickness, or a surface roughness, among other examples) of a feature. Additionally, or alternatively, and in some examples, testing may include testing a quality (e.g., a timing, frequency, or electrical performance) related to a functionality of active circuitry formed on the semiconductive substrate. Additionally, or alternatively, and in some examples, testing may include stressing the active circuitry to determine a reliability of the active circuitry. To perform the testing, the ATE tool 450 may use a contact probe testing technique or another suitable testing technique, among other examples.

As further shown in FIG. 4, the manufacturing system 400 may include a bond tool 455. In some examples, the bond tool 455 may be used to couple two semiconductive substrates (including active circuitry) along a bond interface. The bond interface may include dielectric-to-dielectric bonds, metal-to-metal bonds, or a combination thereof (e.g., the bond interface may be a hybrid-bond interface). To couple the two semiconductive substrates, the bond tool 455 may use a thermal compression technique, an anodic bonding technique, an adhesive bonding technique, a fusion bonding technique, or another suitable bonding technique, among other examples.

Each tool of the manufacturing system 400 may include mechanics, circuitry, logic, means, or instructions (e.g., a non-transitory computer-readable medium storing instructions executable by a processor), or any combination thereof to perform a designated manufacturing operation. During a series of manufacturing operations used as part of forming a feature (e.g., form a feature of a memory device or another semiconductive device), a progression 460 (e.g., a sequence or an ordered use) amongst the tools may be based on a design or a structure of the feature. In some examples, the progression 460 may rely on an entirety of the manufacturing system 400 (e.g., rely on each tool being used). Alternatively, and in some examples, the progression 460 may rely on a portion of the manufacturing system 400 (e.g., rely on a subset of the tools being used).

As described in greater detail with reference to FIGS. 5A - 6, the manufacturing system 400 (e.g., one or more tools of the manufacturing system 400) may perform aspects of a manufacturing process or a method related as part of forming an apparatus (e.g., the 3D NAND memory array 300) having a memory pillar surrounded by a barrier layer that is self-aligned.

FIGS. 5A - 5M show stages of an example manufacturing process 500 that supports formation of an apparatus having a memory pillar surrounded by a barrier layer that is self-aligned in accordance with examples as disclosed herein. Each stage of the manufacturing process 500 may use one or more of the semiconductor manufacturing tools described with reference to FIG. 4.

FIG. 5A shows an example first stage of a partially formed portion of an apparatus (e.g., the 3D NAND memory array 300 described with respect to FIG. 3) after a first set of one or more fabrication operations. In some examples, and as part of the first set of one or more operations, a deposition tool (e.g., the deposition tool 405) may perform a sequence of deposition operations as part of forming a stack of layers 505 over the semiconductive substrate 310. The stack of layers 505 (e.g., used as part of forming the lower deck 350) may include or more sacrificial layer(s) 515 that alternate, interleave, or otherwise are interspersed with one or more conductive layers 325 of the lower deck 350. Each sacrificial layer 515 may include a dielectric material with suitable sacrificial characteristics (e.g., silicon nitride or another dielectric material with suitable characteristics for downstream exhuming or removal from between the one or more conductive layers 325).

In some examples, and as shown in FIG. 5A, the substrate 310 may include one or more temporary fill structures 510. The temporary fill structure(s) 510 may include a dielectric material (e.g., oxide or another suitable dielectric material).

The first set of one or more fabrication operations may further form and pattern a hard mask layer 520 over the stack of layers 505. In some examples, and as part of the first set of one or more fabrication operations, a deposition tool (e.g., the deposition tool 405) may perform a deposition operation as part of forming a hard mask layer 520 (e.g., a layer of carbon or another suitable hard mask material) over the stack of layers 505. Additionally, or alternatively, and as part of the first set of one or more fabrication operations, a lithography tool set (e.g., the lithography tool set 410) and an etch tool (e.g., the etch tool 430) may perform a sequence of patterning and etching operations as part of forming a set of one or more cavities 525 through the hard mask layer 520 and through the stack of layers 505 to the temporary fill structure(s) 510.

FIG. 5B shows an example second stage of a partially formed portion of the apparatus after a second set of one or more fabrication operations. The second set of one or more fabrication operations may remove the hard mask layer 520 in preparation for a subsequent set of one or more fabrication operations that form at least a portion of a barrier layer that is self-aligned (e.g., a sublayer of the barrier layer 375) along sidewalls of the cavity 525. In some examples, and as part of the second set of one or more fabrication operations, an etch tool (e.g., the etch tool 430) may perform an in-situ strip clean operation using a carbon dioxide gas that strips the hard mask layer 520 from the stack of layers 505. The in-situ strip clean operation may further remove biproducts (e.g., residual polymers remaining from an etch operation used to form the cavity 525 as described with reference to FIG. 5A) from sidewalls of the cavity 525.

FIG. 5C shows an example third stage of a partially formed portion of the apparatus after a third set of one or more fabrication operations. The third set of one or more fabrication operations may remove the temporary fill structure(s) 510 and extend a depth of the cavity 525 in preparation for a subsequent set of one or more fabrication operations that form a portion of a barrier layer that is self-aligned (e.g., a sublayer of the barrier layer 375). In some examples, and as part of the third set of one or more fabrication operations, an etch tool an (e.g., the etch tool 430) may perform an etching operation that removes the temporary fill structure(s) 510.

FIG. 5D shows an example fourth stage of a partially formed portion of the apparatus after a fourth set of one or more fabrication operations. The fourth set of one or more fabrication operations may form a sublayer 380-a (of the barrier layer 375) along a contour of the cavity 525, including a bowed portion in the stack of layers 505 (e.g., the lower deck 350) and an angled portion in the semiconductive substrate 310. Additionally, or alternatively, the fourth set of one or more fabrications may form at least a portion of the sublayer 380-a over and along a top layer of the stack of layers 505. In some examples, and as part of the fourth set of one or more fabrication operations, a deposition tool (e.g., the deposition tool 405) may perform a deposition operation that deposits a dielectric material (e.g., an oxide or another suitable dielectric material) as part of forming the sublayer 380-a.

FIG. 5E shows an example fifth stage of a partially formed portion of the apparatus after a fifth set of one or more fabrication operations. The fifth set of one or more fabrication operations may form a temporary lower pillar segment 535 in the cavity 525. In some examples, and as part of the fifth set of one or more fabrication operations, a deposition tool (e.g., the deposition tool 405) may perform a deposition operation that deposits carbon as part of forming the temporary lower pillar segment 535. Additionally, or alternatively, and as part of the fifth set of one or more operations, the deposition tool may perform an in-situ recessing operation that recesses the temporary lower pillar segment 535.

FIG. 5F shows an example sixth stage of a partially formed portion of the apparatus after a sixth set of one or more fabrication operations. The sixth set of one or more fabrication operations may include removing portions of the sublayer 380-a to expose sacrificial layer(s) 515 and conductive layer(s) 325 in the cavity 525. The sixth set of one or more fabrication operations may further include recessing an upper portion of the cavity 525 to establish a depth of a subsequently formed temporary middle pillar segment in the cavity 525. In some examples, and as part of the sixth set of one or more fabrication operations, an etch tool (e.g., the etch tool 430) may perform an etch operation that removes the portions of the sublayer 380-a. Additionally, or alternatively, an etch tool (e.g., the etch tool 430) may perform an etch operation that is selective to a material (e.g., carbon) included in the temporary lower pillar segment 535 to recess the upper portion of the cavity 525.

FIG. 5G shows an example seventh stage of a partially formed portion of the apparatus after a seventh set of one or more fabrication operations. The seventh set of one or more fabrication operations may remove portions of the stack of layers 505 and the sublayer 380-a to increase a width W of the upper portion of the cavity 525 and form recesses 540 in the sublayer 380-a that extend below a top-most surface of the temporary lower pillar segment 535. Additionally, or alternatively, the seventh set of one or more fabrication operations may contribute to forming the cavity 525 such that a subsequently formed middle pillar segment (e.g., the middle segment 365-c) in the cavity 525 is proximate one or more dummy word lines 545 (e.g., inactive word lines of the 3D NAND memory array 300). In some examples, and as part of the seventh set of one or more fabrication operations, an etch tool (e.g., the etch tool 430) may perform an etch operation that pulls back portions of the stack of layers 505 (e.g., portions of the sacrificial layer(s) 515 or the dielectric layer(s) 320) and the sublayer 380-a.

FIG. 5H shows an example eighth stage of a partially formed portion of the apparatus after an eighth set of one or more fabrication operations. The eighth set of one or more fabrication operations may, as part of forming a temporary middle pillar segment described with reference to FIG. 5I, form a liner 550 including portions along the contour of the cavity 525 and over the stack of layers 505. In some examples, and as part of the eighth set of one or more fabrication operations, a deposition tool (e.g., the deposition tool 405) may perform a deposition operation that deposits aluminum oxide (or another suitable material) as part of forming the liner 550.

FIG. 5I shows an example ninth stage of a partially formed portion of the apparatus after a ninth set of one or more fabrication operations. The ninth set of one or more fabrication operations may, as part of forming a temporary middle pillar segment 555, form a fill 560 over the liner 550. In some examples, and as part of the ninth set of one or more fabrication operations, a deposition tool (e.g., the deposition tool 405) may perform a deposition operation that deposits borophosphosilicate glass (BPSG) (or another suitable material) over the liner 550. Additionally, or alternatively, a planarization tool (e.g., the planarization tool 445) may, using a chemical-mechanical planarization (CMP) technique, perform a planarization operation that removes portions of the liner 550 and the fill 560 as part of forming the temporary middle pillar segment 555.

FIG. 5J shows an example tenth stage of a partially formed portion of the apparatus after a tenth set of one or more fabrication operations. The tenth set of one or more fabrication operations may form a stack of layers 565 over the stack of layers 505. In some examples, and as part of the tenth set of one or more operations, a deposition tool (e.g., the deposition tool 405) may perform a sequence of deposition operations as part of forming the stack of layers 565 over the stack of layers 505. The stack of layers 565 (e.g., used in forming the upper deck 355) may include one or more sacrificial layers 515 that alternate, interleave, or otherwise are interspersed with one or more conductive layers 325 of the upper deck 355.

FIG. 5K shows an example eleventh stage of a partially formed portion of the apparatus after an eleventh set of one or more fabrication operations. The eleventh set of one or more fabrication operations may form a cavity 570 through the stack of layers 565 to the temporary middle pillar segment 555 in preparation for removing the temporary middle pillar segment 555 and the temporary lower pillar segment 535. In some examples, and as part of the eleventh set of one or more fabrication operations, a lithography tool set (e.g., the lithography tool set 410) and an etch tool (e.g., the etch tool 430) may perform a sequence of patterning and etching operations as part of forming the cavity 570 through the stack of layers 565 to the temporary middle pillar segment 555.

FIG. 5L shows an example twelfth stage of a partially formed portion of the apparatus after a twelfth set of one or more fabrication operations. The twelfth set of one or more fabrication operations may remove the temporary middle pillar segment 555 and the temporary lower pillar segment 535 in preparation for forming another sublayer of the barrier layer that is self-aligned (e.g., another sublayer of the barrier layer 375). In some examples, and as part of the twelfth set of one or more fabrication operations, an etch tool (e.g., the etch tool 430) may perform an etching operation that removes the temporary middle pillar segment 555 and the temporary lower pillar segment 535. As shown in FIG. 5L, the twelfth set of one or more fabrication operations may expose the sublayer 380-a.

FIG. 5M shows an example thirteenth stage of a partially formed portion of the apparatus after a thirteenth set of one or more fabrication operations. The thirteenth set of one or more fabrication operations may form a sublayer 380-b (of the barrier layer 375) along the sublayer 380-a, along a contour of an upper portion of the cavity 525, and along a contour of the cavity 570. In some examples, and as part of the thirteenth set of one or more fabrication operations, a deposition tool (e.g., the deposition tool 405) may perform a deposition operation that deposits a dielectric material (e.g., oxide or another suitable dielectric material) as part of forming the sublayer 380-b.

As shown in FIG. 5M, a portion of the barrier layer 375 corresponding to a lower portion of the barrier layer 375 may include a portion of the sublayer 380-b that is along (e.g., physically coupled with) the sublayer 380-a. Additionally, a portion of the barrier layer 375 corresponding to an upper portion of the barrier layer 375 may include a portion of the sublayer 380-b. In some examples, a thickness of the segment corresponding to the lower portion (e.g., a combined thickness of the sublayer 380-a and the sublayer 380-b) is greater than a thickness of the segment corresponding to the upper portion (e.g., a thickness of the sublayer 380-b). Further, a thickness of the barrier layer 375 may be substantially uniform in the transitional region 360.

FIG. 5N shows an example fourteenth stage of a partially formed portion of the apparatus after a fourteenth set of one or more fabrication operations. The fourteenth set of one or more fabrication operations may include forming the dielectric layer 370 and the pillar 330 (e.g., including the lower segment 365-a, the upper segment 365-b, and the middle segment 365-c). The fourteenth set of one or more fabrication operations may further include forming the stack of layers 315. In some examples, and as part of the fourteenth set of one or more fabrication operations, a deposition tool (e.g., the deposition tool 405) may perform a deposition operation that forms the dielectric layer 370 along a contour of the barrier layer 375. Additionally, or alternatively, a deposition tool (e.g., the deposition tool 405) may perform a sequence of one or more deposition operations that deposit one or more semiconductive layers or one or more dielectric layers along a contour of the barrier layer 375 as part of forming the pillar 330. Additionally, or alternatively, an etch tool (e.g., the etch tool 430) may perform an etch operation that, using an exhuming technique, removes sacrificial layers (e.g., the sacrificial layer(s) 515) from between the dielectric layer(s) 320. Additionally, or alternatively, a deposition tool (e.g., the deposition tool 405) may perform a deposition operation that deposits the conductive layer(s) 325 as part of forming the stack of layers 315.

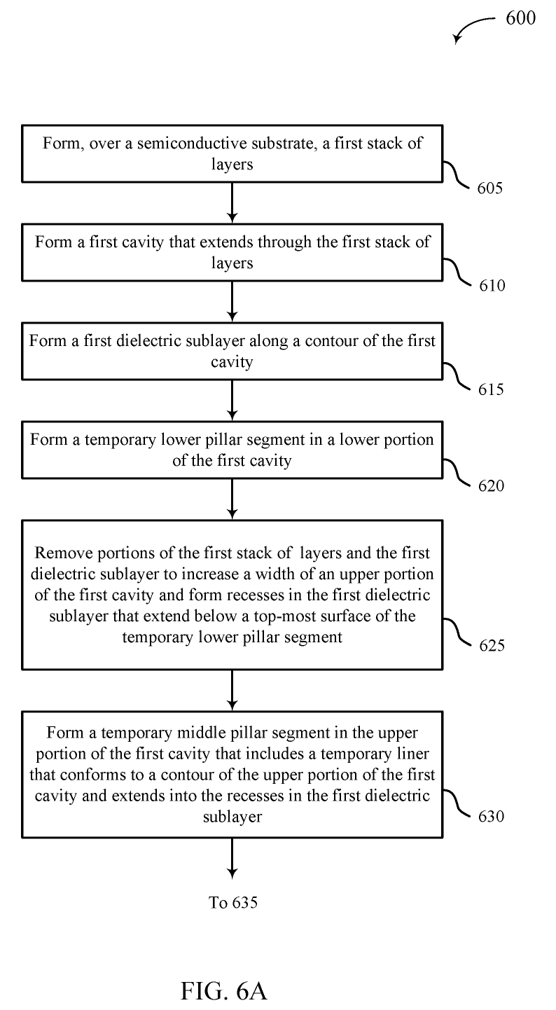

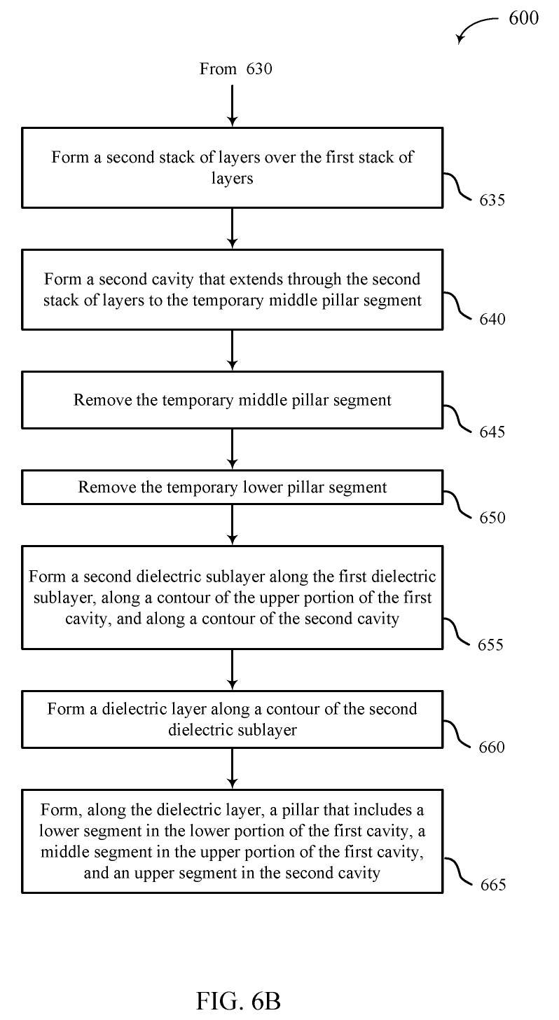

FIG. 6 shows a flowchart illustrating a method 600 that supports an apparatus having a memory pillar surrounded by a barrier layer that is self-aligned in accordance with examples as disclosed herein. The operations of method 600 may be implemented by a manufacturing system or its components as described herein. For example, the operations of method 600 may be performed by a manufacturing system as described with reference to FIG. 4 or one of the manufacturing stages as described with reference to FIGS. 5A - 5N.

In some examples, a semiconductor manufacturing tool of the manufacturing system 400 may execute a set of instructions to control the functional elements of the semiconductor manufacturing tool to perform the described functions. Additionally, or alternatively, the semiconductor manufacturing tool may perform aspects of the described functions using special-purpose hardware.

At 605, the method may include forming, over a semiconductive substrate, a first stack of layers. In some examples, aspects of the operations of 605 may be performed by one or more semiconductor manufacturing tools, including the deposition tool 405 as described with reference to FIG. 4 or another suitable semiconductor manufacturing tool, among other examples.

At 610, the method may include forming a first cavity that extends through the first stack of layers. In some examples, aspects of the operations of 610 may be performed by one or more semiconductor manufacturing tools, including the lithography tool set 410 and the etch tool 430 as described with reference to FIG. 4 or another suitable semiconductor manufacturing tool, among other examples.

At 615, the method may include forming a first dielectric sublayer along a contour of the first cavity. In some examples, aspects of the operations of 615 may be performed by one or more semiconductor manufacturing tools, including the deposition tool 405 as described with reference to FIG. 4 or another suitable semiconductor manufacturing tool, among other examples.

At 620, the method may include forming a temporary lower pillar segment in a lower portion of the first cavity. In some examples, aspects of the operations of 620 may be performed by one or more semiconductor manufacturing tools, including the deposition tool 405 as described with reference to FIG. 4 or another suitable semiconductor manufacturing tool, among other examples.

At 625, the method may include removing portions of the first stack of layers and the first dielectric sublayer to increase a width of an upper portion of the first cavity and form recesses in the first dielectric sublayer that extend below a top-most surface of the temporary lower pillar segment. In some examples, aspects of the operations of 625 may be performed by one or more semiconductor manufacturing tools, including the etch tool 430 as described with reference to FIG. 4 or another suitable semiconductor manufacturing tool, among other examples.

At 630, the method may include forming a temporary middle pillar segment in the upper portion of the first cavity that includes a temporary liner that conforms to a contour of the upper portion of the first cavity and extends into the recesses in the first dielectric sublayer. In some examples, aspects of the operations of 630 may be performed by one or more semiconductor manufacturing tools, including the deposition tool 405 as described with reference to FIG. 4 or another suitable semiconductor manufacturing tool, among other examples.

At 635, the method may include forming a second stack of over the first stack of layers. In some examples, aspects of the operations of 635 may be performed by one or more semiconductor manufacturing tools, including the deposition tool 405 as described with reference to FIG. 4 or another suitable semiconductor manufacturing tool, among other examples.

At 640, the method may include forming a second cavity that extends through the second stack of layers to the temporary middle pillar segment. In some examples, aspects of the operations of 640 may be performed by one or more semiconductor manufacturing tools, including the etch tool 430 as described with reference to FIG. 4 or another suitable semiconductor manufacturing tool, among other examples.

At 645, the method may include removing the temporary middle pillar segment. In some examples, aspects of the operations of 645 may be performed by one or more semiconductor manufacturing tools, including the etch tool 430 as described with reference to FIG. 4 or another suitable semiconductor manufacturing tool, among other examples.

At 650, the method may include removing the temporary lower pillar segment. In some examples, aspects of the operations of 650 may be performed by one or more semiconductor manufacturing tools, including the etch tool 430 as described with reference to FIG. 4 or another suitable semiconductor manufacturing tool, among other examples.

At 655, the method may include forming a second dielectric sublayer along the first dielectric sublayer, along a contour of the upper portion of the first cavity, and along a contour of the second cavity. In some examples, aspects of the operations of 655 may be performed by one or more semiconductor manufacturing tools, including the deposition tool 405 as described with reference to FIG. 4 or another suitable semiconductor manufacturing tool, among other examples.

At 660, the method may include forming a dielectric layer along a contour of the second dielectric sublayer. In some examples, aspects of the operations of 660 may be performed by one or more semiconductor manufacturing tools, including the deposition tool 405 as described with reference to FIG. 4 or another suitable semiconductor manufacturing tool, among other examples.

At 665, the method may include forming, along the dielectric layer, a pillar that includes a lower segment in the lower portion of the first cavity, a middle segment in the upper portion of the first cavity, and an upper segment in the second cavity. In some examples, aspects of the operations of 665 may be performed by one or more semiconductor manufacturing tools, including the deposition tool 405 as described with reference to FIG. 4 or another suitable semiconductor manufacturing tool, among other examples.

In some examples, a manufacturing system (e.g., the manufacturing system 400, a semiconductor manufacturing tool of the manufacturing system 400, or another suitable tool) described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming, over a semiconductive substrate, a first stack of layers; forming a first cavity that extends through the first stack of layers; forming a first dielectric sublayer along a contour of the first cavity; forming a temporary lower pillar segment in a lower portion of the first cavity; removing portions of the first stack of layers and the first dielectric sublayer to increase a width of an upper portion of the first cavity and form recesses in the first dielectric sublayer that extend below a top-most surface of the temporary lower pillar segment; forming a temporary middle pillar segment in the upper portion of the first cavity that includes a temporary liner that conforms to a contour of the upper portion of the first cavity and extends into the recesses in the first dielectric sublayer; forming a second stack of layers over the first stack of layers; forming a second cavity that extends through the second stack of layers to the temporary middle pillar segment; removing the temporary middle pillar segment to expose the recesses in the first dielectric sublayer; removing the temporary lower pillar segment; forming a second dielectric sublayer along the first dielectric sublayer, along a contour of the upper portion of the first cavity, and along a contour of the second cavity; forming a dielectric layer along a contour of the second dielectric sublayer; and forming, along the dielectric layer, a pillar that includes a lower segment in the lower portion of the first cavity, a middle segment in the upper portion of the first cavity, and an upper segment in the second cavity.

Aspect 2: The method, apparatus, or non-transitory computer-readable medium of aspect 1, where operations, features, circuitry, logic, means, or instructions, or any combination thereof for forming the first cavity include operations, features, circuitry, logic, means, or instructions, or any combination thereof for forming a patterned hard mask over an oxide layer that is on the first stack of layers and forming the first cavity through the first stack of layers and into the semiconductive substrate using an etch operation that removes portions of the first stack of layers and the semiconductive substrate through the patterned hard mask.

Aspect 3: The method, apparatus, or non-transitory computer-readable medium of aspect 2, further including operations, features, circuitry, logic, means, or instructions, or any combination thereof for removing the patterned hard mask via an in situ operation that uses a carbon dioxide gas.

Aspect 4: The method, apparatus, or non-transitory computer-readable medium of any of aspects 1 through 3, where operations, features, circuitry, logic, means, or instructions, or any combination thereof for forming the first dielectric sublayer include operations, features, circuitry, logic, means, or instructions, or any combination thereof for forming the first dielectric sublayer using a deposition operation that deposits an oxide along the contour of the first cavity and along a surface of an oxide layer that is on the first stack of layers.

Aspect 5: The method, apparatus, or non-transitory computer-readable medium of any of aspects 1 through 4, where operations, features, circuitry, logic, means, or instructions, or any combination thereof for forming the temporary lower pillar segment include operations, features, circuitry, logic, means, or instructions, or any combination thereof for forming the temporary lower pillar segment using a deposition operation that deposits carbon in the first cavity and an in-situ removal operation that recesses the carbon in the first cavity.

Aspect 6: The method, apparatus, or non-transitory computer-readable medium of any of aspects 1 through 5, where operations, features, circuitry, logic, means, or instructions, or any combination thereof for removing the portions of the first stack of layers and the first dielectric sublayer include operations, features, circuitry, logic, means, or instructions, or any combination thereof for removing the portions of the first stack of layers and the first dielectric sublayer using an etch operation that is selective to a material of the temporary lower pillar segment to increase the width of the upper portion of the first cavity, form the recesses in the first dielectric sublayer that extend below a top-most surface of the temporary lower pillar segment, and establish a depth of the upper portion of the first cavity.

Aspect 7: The method, apparatus, or non-transitory computer-readable medium of any of aspects 1 through 6, where operations, features, circuitry, logic, means, or instructions, or any combination thereof for forming the temporary middle pillar segment include operations, features, circuitry, logic, means, or instructions, or any combination thereof for forming the temporary liner of the temporary middle pillar segment using a deposition operation that deposits an oxide along the contour of the upper portion of the first cavity and in the recesses in the first dielectric sublayer.

Aspect 8: The method, apparatus, or non-transitory computer-readable medium of any of aspects 1 through 7, where operations, features, circuitry, logic, means, or instructions, or any combination thereof for forming the second dielectric sublayer include operations, features, circuitry, logic, means, or instructions, or any combination thereof for forming the second dielectric sublayer using a deposition operation that deposits an oxide along a contour of the upper portion of the first cavity, along a contour of the second cavity, and in the recesses in the first dielectric sublayer, where the recesses self-align the second dielectric sublayer with the first dielectric sublayer.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: a semiconductive substrate; a stack of layers above the semiconductive substrate, and the stack of layers including: an upper deck; and a lower deck; a pillar passing through the stack of layers into the semiconductive substrate, the pillar including: an upper segment including at least a portion in the upper deck; a lower segment including at least a portion in the lower deck; and a middle segment in the lower deck, the middle segment between the upper segment and the lower segment (e.g., the middle segment physically or electrically couples the upper segment with the lower segment); and a multi-layer structure surrounding the pillar, the multi-layer structure including: a dielectric layer along the pillar; and a barrier layer along the dielectric layer, the barrier layer including: a first portion having a first thickness; and a second portion having a second thickness at least partially along (e.g., at least partially physically coupled with) the first portion where the second thickness is less than the first thickness and is substantially uniform in a transitional region that includes at least a portion of the lower segment of the pillar and at least a portion of the upper segment of the pillar.

Aspect 10: The apparatus of aspect 9, where the barrier layer is substantially uniform in the transitional region, the transitional region further including the middle segment of the pillar.

Aspect 11: The apparatus of any of aspects 9 through 10, where a cross-sectional shape of the barrier layer along the pillar in the transitional region is a substantially round, annular cross-sectional shape.

Aspect 12: The apparatus of any of aspects 9 through 11, where the first portion of the barrier layer includes: a portion of a first sublayer that is along (e.g., physically coupled with) an entire portion of a second sublayer.

Aspect 13: The apparatus of any of aspects 9 through 12, where the first portion of the barrier layer is at least partially along (e.g., at least partially physically coupled with) a portion of the dielectric layer along the lower segment of the pillar.

Aspect 14: The apparatus of any of aspects 9 through 13, where a contour of the first portion of the barrier layer matches a contour of the portion of the dielectric layer along the lower segment of the pillar.

Aspect 15: The apparatus of aspect 14, where the contour of the first portion of the barrier layer along the lower segment includes a bowed portion in lower deck.

Aspect 16: The apparatus of any of aspects 14 through 15, where the contour of the first portion of the barrier layer along the lower segment includes an angled portion in the semiconductive substrate.

Aspect 17: The apparatus of any of aspects 9 through 16, where the second portion of the barrier layer includes: a portion of a first sublayer that is at least partially along (e.g., at least partially physically coupled with) a portion of the dielectric layer along the middle segment of the pillar and the upper segment of the pillar.

Aspect 18: The apparatus of aspect 17, where a contour of the second portion of the barrier layer matches a contour of the portion of the dielectric layer along the middle segment of the pillar and the upper segment of the pillar.

An apparatus is described. The following provides an overview of aspects of the apparatus as described herein:

Aspect 19: An apparatus, including: a word line structure including a conductive layer between two dielectric layers; a NAND pillar, including: an upper segment; a lower segment; and a middle segment that couples (e.g., electrically or physically) the upper segment with the lower segment and passes through the word line structure; and a multi-layer structure surrounding the middle segment, the multi-layer structure including: a barrier layer having a thickness that is substantially uniform along a contour of the middle segment of the NAND pillar; and a charge trapping layer between the barrier layer and the NAND pillar. The barrier layer may have a substantially round, annular cross-sectional shape along the contour of the middle segment of the NAND pillar.

Aspect 20: The apparatus of aspect 19, where the barrier layer is free of protrusions that extend from the middle segment of the NAND pillar and towards the word line structure.

Aspect 21: The apparatus of any of aspects 19 through 20, where the apparatus satisfies a threshold related to voltage degradation based at least in part on the substantially round, annular cross-sectional shape of the barrier layer in combination with a uniformity of a thickness of the barrier layer.

Aspect 22: The apparatus of any of aspects 19 through 21, where a thickness of the charge trapping layer is greater than the thickness of the barrier layer.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” may refer to electrical relationships between components (e.g., “electrically coupling”), may refer to physical relationships between components (e.g., “physically coupling”), or may refer to a combination of electrical and physical relationships. For electrical relationships, the term “coupling” (or its derivatives) may refer to a condition of moving from an open-circuit relationship between components in which signals are not capable of being communicated between the components over a conductive path to a closed-circuit relationship between components in which signals are capable of being communicated between components over the conductive path. If a component, such as a controller, couples components with one another, the component initiates a change that allows signals to be communicated between the other components over a conductive path that previously did not permit signals to flow. For physical relationships, the term “coupling” (or its derivatives) may refer to a physical joining of components, including layers, levels, or materials associated with the components. In some examples, the physical joining may be direct and may be along an interface or interface region between the components. Additionally, or alternatively, the physical joining may be indirect, in which one or more intervening components are used as part of the physical joining of the components.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a semiconductive substrate;
a stack of layers above the semiconductive substrate, the stack of layers having conductive layers alternating with dielectric layers, and the stack of layers comprising:
an upper deck; and
a lower deck;
a pillar passing through the stack of layers into the semiconductive substrate, the pillar comprising:
an upper segment including at least a portion in the upper deck;
a lower segment including at least a portion in the lower deck; and
a middle segment in the lower deck, the middle segment between the upper segment and the lower segment; and
a multi-layer structure surrounding the pillar, the multi-layer structure comprising:
a dielectric layer along the pillar; and
a barrier layer along the dielectric layer, the barrier layer comprising:
a first portion having a first thickness; and
a second portion having a second thickness at least partially along the first portion, wherein the second thickness is less than the first thickness and is substantially uniform in a transitional region that comprises at least a portion of the lower segment of the pillar and at least a portion of the upper segment of the pillar.

2. The apparatus of claim 1, wherein a thickness of the barrier layer is substantially uniform in the transitional region, the transitional region further comprising the middle segment of the pillar.

3. The apparatus of claim 1, wherein a cross-sectional shape of the barrier layer along the pillar in the transitional region is a substantially round, annular cross-sectional shape.

4. The apparatus of claim 1, wherein the first portion of the barrier layer comprises:
a portion of a first sublayer that is along an entire portion of a second sublayer.

5. The apparatus of claim 1, wherein the first portion of the barrier layer is at least partially along a portion of the dielectric layer along the lower segment of the pillar.

6. The apparatus of claim 1, wherein a contour of the first portion of the barrier layer matches a contour of the portion of the dielectric layer along the lower segment of the pillar.

7. The apparatus of claim 6, wherein the contour of the portion of the first portion of the barrier layer along the lower segment comprises a bowed portion in lower deck.

8. The apparatus of claim 6, wherein the contour of the first portion of the barrier layer along the lower segment comprises an angled portion in the semiconductive substrate.

9. The apparatus of claim 1, wherein the second portion of the barrier layer comprises:
a portion of a first sublayer that is at least partially along a portion of the dielectric layer along the middle segment of the pillar and the upper segment of the pillar.

10. The apparatus of claim 9, wherein a contour of the second portion of the barrier layer matches a contour of the portion of the dielectric layer along the middle segment of the pillar and the upper segment of the pillar.

11. An apparatus, comprising:
a word line structure comprising a conductive layer between two dielectric layers;
a NAND pillar, comprising:
an upper segment;
a lower segment; and
a middle segment that couples the upper segment with the lower segment and passes through the word line structure; and
a multi-layer structure surrounding the NAND pillar, the multi-layer structure comprising:
a barrier layer having a thickness that is substantially uniform along a contour of the middle segment of the NAND pillar; and
a charge trapping layer between the barrier layer and the NAND pillar, the charge trapping layer having a substantially round, annular cross-sectional shape along the contour of the middle segment of the NAND pillar.

12. The apparatus of claim 11, wherein the charge trapping layer is free of protrusions that extend from the middle segment and towards the word line structure.

13. The apparatus of claim 11, wherein the apparatus satisfies a threshold related to voltage degradation based at least in part on the substantially round, annular cross-sectional shape of the barrier layer in combination with a uniformity of a thickness of the barrier layer.

14. The apparatus of claim 11, wherein a thickness of the charge trapping layer is greater than the thickness of the barrier layer.

15. A method, comprising:
forming, over a semiconductive substrate, a first stack of layers;
forming a first cavity that extends through the first stack of layers;
forming a first dielectric sublayer along a contour of the first cavity;
forming a temporary lower pillar segment in a lower portion of the first cavity;
removing portions of the first stack of layers and the first dielectric sublayer to increase a width of an upper portion of the first cavity and form recesses in the first dielectric sublayer that extend below a top-most surface of the temporary lower pillar segment;
forming a temporary middle pillar segment in the upper portion of the first cavity that comprises a temporary liner that conforms to a contour of the upper portion of the first cavity and extends into the recesses in the first dielectric sublayer;
forming a second stack of layers over the first stack of layers;
forming a second cavity that extends through the second stack of layers to the temporary middle pillar segment;
removing the temporary middle pillar segment;
removing the temporary lower pillar segment;
forming a second dielectric sublayer along the first dielectric sublayer, along a contour of the upper portion of the first cavity, and along a contour of the second cavity;
forming a dielectric layer along a contour of the second dielectric sublayer; and
forming, along the dielectric layer, a pillar that includes a lower segment in the lower portion of the first cavity, a middle segment in the upper portion of the first cavity, and an upper segment in the second cavity.

16. The method of claim 15, wherein forming the first cavity comprises:
forming a patterned hard mask over an oxide layer that is on the first stack of layers; and
forming the first cavity through the first stack of layers and into the semiconductive substrate using an etch operation that removes portions of the first stack of layers and the semiconductive substrate through the patterned hard mask.

17. The method of claim 16, further comprising:
removing the patterned hard mask via an in situ operation that uses a carbon dioxide gas.

18. The method of claim 15, wherein forming the first dielectric sublayer comprises:
forming the first dielectric sublayer using a deposition operation that deposits oxide along the contour of the first cavity.

19. The method of claim 15, wherein forming the temporary lower pillar segment comprises:
forming the temporary lower pillar segment using a deposition operation that deposits carbon in the first cavity and an in-situ removal operation that recesses the carbon in the first cavity.

20. The method of claim 15, wherein removing the portions of the first stack of layers and the first dielectric sublayer comprises:
removing the portions of the first stack of layers and the first dielectric sublayer using an etch operation that is selective to a material of the temporary lower pillar segment to increase the width of the upper portion of the first cavity, form the recesses in the first dielectric sublayer that extend below a top-most surface of the temporary lower pillar segment, and establish a depth of the upper portion of the first cavity.

21. The method of claim 15, wherein forming the temporary middle pillar segment comprises:
forming the temporary liner of the temporary middle pillar segment using a deposition operation that deposits the temporary liner along the contour of the upper portion of the first cavity and in the recesses in the first dielectric sublayer.

22. The method of claim 15, wherein forming the second dielectric sublayer comprises:
forming the second dielectric sublayer using a deposition operation that deposits oxide along a contour of the upper portion of the first cavity, along a contour of the second cavity, and in the recesses in the first dielectric sublayer, wherein the recesses self-align the second dielectric sublayer with the first dielectric sublayer.
